(19) United States
(12) Patent Application Publication
(10) Pub. No.: US 2025/0336872 A1
(43) Pub. Date: Oct. 30, 2025

(54) MICROELECTRONIC DEVICE PACKAGE WITH EMBEDDED SEMICONDUCTOR DIES INTEGRATED WITH INTEGRAL PASSIVE COMPONENTS

(71) Applicant: Texas Instruments Incorporated, Dallas, TX (US)

(72) Inventors: Kuan-Ting Liu, Taichung City (TW); FuKang Lee, New Taipei City (TW); Hsiu-Yang Kuo, Taipei (TW)

(21) Appl. No.: 18/650,298

(22) Filed: Apr. 30, 2024

(51) Int. Cl. H01L 23/00; H01L 23/31; H01L 23/498; H01L 27/06

(52) U.S. Cl. CPC H01L 24/20; H01L 23/3128; H01L 23/3135; H01L 23/49816; H01L 24/19; H01L 24/96; H10D 88/00; H01L 2224/19; H01L 2224/2105; H01L 2224/214; H01L 2224/95001; H01L 2224/96; H01L 2924/01029; H01L 2924/01079

(57) ABSTRACT

An example microelectronic device package includes an integrated system device, further including: at least two semiconductor dies embedded in dielectric material and spaced from one another; layers of trace level conductors formed over the at least two semiconductor dies, and layers of connection level conductors extending through layers of dielectric material between the layers of trace level conductors, the integrated system device having conductive lands on a board side surface exposed from dielectric material. A package substrate has a first set of conductive leads on one side spaced from a second set of conductive leads on an opposite side. The conductive lands are mounted to internal ends of the first set of conductive leads and to internal ends of the second set of conductive leads. Mold compound covers the integrated system device, portions of the first set of leads, and portions of the second set of leads.

### TECHNICAL FIELD

This disclosure relates generally to microelectronic device packages, and more particularly to microelectronic device packages using semiconductor dies embedded in a package substrate.

### BACKGROUND

Processes for producing microelectronic device packages include mounting a semiconductor die to a package substrate and covering the electronic devices with a dielectric material, such as a mold compound, to form packaged devices.

Incorporating passive components such as capacitors, inductors, and coils with semiconductor devices in a microelectronic device package is desirable. Power package applications include packaging using passive components such as inductors and coils with semiconductor devices to increase performance and reduce board area, and to make the microelectronic device package with the passives needed for a normal configuration increases ease of use and reduces board design time. Often a passive component is mounted next to or mounted on or over a completely packaged semiconductor device.

Prior approaches include the use of expensive printed circuit board (PCB) package substrates, which are sometimes used inside a molded device package with mold compound covering the semiconductor devices and the passive components. Adding passive components to packaged semiconductor devices using brackets or mounts on the exterior of semiconductor device packages can be done, but these solutions are relatively high in cost and require substantial package volume in a system. Making molded microelectronic device packages that are efficient and cost-effective while including semiconductor dies and passive components within the microelectronic device packages remains challenging.

### SUMMARY

In a described example, a method includes forming an integrated system device by performing: embedding at least two semiconductor dies spaced from one another in dielectric material, forming layers of trace level conductors layers over the dielectric material, the layers of trace level conductors spaced by additional dielectric material, at least one of the trace level conductors electrically coupled to at least one of the at least two semiconductor dies, forming layers of connection level conductors extending through the additional dielectric material and coupling trace level conductors, the integrated system device having a board side surface with conductive lands exposed from the dielectric material. The method continues by depositing solder balls on internal ends of a first set of conductive leads that are positioned on one side of a package substrate and on internal ends of a second set of conductive leads that are positioned on an opposite side of a package substrate, the first set of conductive leads spaced from the second set of conductive leads. The method then continues by positioning the board side surface of the integrated system device to face the internal ends of the first set of conductive leads and the internal ends of the second set of conductive leads; and using the solder balls, forming solder joints between ones of the conductive lands and corresponding ones of the internal ends of the first set of leads and corresponding ones of the internal ends of the second set of leads. The method then continues by covering the integrated system device, the solder joints, portions of the first set and second set of leads with mold compound to form a microelectronic device package.

In a further described example, a microelectronic device package includes: an integrated system device that includes at least two semiconductor dies embedded in dielectric material and spaced from one another by the dielectric material; layers of trace level conductors formed over the at least two semiconductor dies and spaced from one another by layers of additional dielectric material; and at least one of the layers of trace level conductors electrically coupled to at least one of the at least two semiconductor dies, layers of connection level conductors extending through the layers of additional dielectric material between the layers of trace level conductors and coupling trace level conductors, the integrated system device having a board side surface with conductive lands formed by one of the layers of trace level conductors or of one of the layers of connection level conductors exposed from the layers of additional dielectric material. The microelectronic device package further includes: a first set of conductive leads on one side of a package substrate spaced from and electrically isolated from a second set of conductive leads on an opposite side of the package substrate. The conductive lands of the board side surface of the integrated system device are mounted to internal ends of the first set of conductive leads and to internal ends of the second set of conductive leads. Mold compound covers the integrated system device, portions of the first set of leads, and portions of the second set of leads.

An additional example method includes: forming an integrated system device, by performing embedding a first semiconductor die and a second semiconductor die in dielectric material and spaced from one another by the dielectric material, forming layers of trace level conductors over the first semiconductor die and the second semiconductor die, the layers of trace level conductors spaced from one another by additional layers of dielectric material, at least one level of the trace level conductors electrically coupled to the first semiconductor die or the second semiconductor die, forming layers of connection level conductors between the layers of trace level conductors extending through the additional layers of dielectric material and coupling layers of the trace level conductors, forming a first coil and a second coil using layers of the trace level conductors, the first coil and the second coil spaced from one another by the layers of additional dielectric material and electrically isolated from one another, the first semiconductor die coupled to the first coil and electrically isolated from the second coil, the second semiconductor die coupled to the second coil and electrically isolated from the first coil, and forming conductive lands from one of the layers of trace level conductors or from one of the layers of connection level conductors exposed from the additional layers of dielectric material on a board side surface of the integrated system device. The method continues by forming solder balls on internal ends of a first set of conductive leads on one side of a package substrate and on internal ends of a second set of conductive leads on an opposite side of the package substrate. The method then continues by positioning the board side surface of the integrated system device to face the internal ends of the first set of conductive leads and the internal ends of the second set of conductive leads. Solder joints are formed using the solder balls, forming solder joints between ones of the conductive lands and corresponding ones of the internal ends of the first set of conductive leads and corresponding ones of the internal ends of the second set of conductive leads. The method continues by covering the integrated system device, the solder joints, portions of the first set of conductive leads, and portions of the second set of conductive leads with mold compound to form a microelectronic device package.

### BRIEF DESCRIPTION OF THE DRAWINGS

FIGS. 1A-1B illustrate, in a projection view and a close-up projection view, respectively, semiconductor dies on a semiconductor wafer and an individual semiconductor die from the semiconductor wafer, for use with the arrangements.

FIGS. 2A-2B illustrate, in a projection view and a cross-sectional view, respectively, a microelectronic device package of an example arrangement. FIG. 2C illustrates, in a partially transparent projection view, a microelectronic device package illustrating further details.

FIGS. 3A-3B illustrate, in cross-sectional views, microelectronic device package of an example arrangement (FIG. 3A) and in a close-up view, details of the example arrangement (FIG. 3B).

FIGS. 4A-4B, 4BB, 4C, 4CC, 4D, 4DD, 4DDD, and 4E-4K illustrate, in a series of cross-sectional views, selected steps useful in manufacturing an integrated system device of the arrangements.

FIGS. 5A-5D illustrate, in a series of cross-sectional views, selected steps for forming a microelectronic device package of the arrangements.

FIGS. 6A-6C illustrate, in additional cross-sectional views, selected steps for forming an alternative microelectronic device package of the arrangements.

FIG. 7 illustrates, in a flow diagram, selected steps of a method for forming a multilayer package substrate for use in example arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, discrete devices such as a pair of power field effect transistor (FET) switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. When semiconductor devices are fabricated on a semiconductor wafer and then individually separated from the semiconductor wafer, the individual units are referred to as “semiconductor dies.” A semiconductor die is also a semiconductor device.

The term “passive component” is used herein. As used herein, a passive component is a component without active devices, for example, a resistor, capacitor, inductor, coil, diode, or sensor. Examples useful in the arrangements include capacitors, diodes, resistors, inductors, coils, or transformers formed from multiple coils.

The term “microelectronic device package” is used herein. A microelectronic device package has at least one semiconductor die electrically coupled to terminals and has a package body that protects and covers the semiconductor die. The microelectronic device package can include additional elements. In some example arrangements a passive component, or multiple passive components, are included. Passive components such as diodes, capacitors, resistors, inductors, coils, or transformers can be included. In some arrangements, multiple semiconductor dies can be included. The semiconductor dies are mounted to a package substrate that provides conductive leads; a portion of the conductive leads form the terminals for the microelectronic device package. A semiconductor die can be mounted with a device side facing towards a device side surface of the package substrate using conductive post connects, in a flip chip package. The microelectronic device package can have a package body formed by a thermoset epoxy resin in a molding process, or using epoxy, plastics, or resins that are liquid at room temperature and are subsequently cured. The package body may provide a hermetic package for the packaged device. The package body may be formed in a mold using an encapsulation process, however, a portion of the leads of the package substrate may not be covered during encapsulation, these exposed lead portions can provide the terminals for the microelectronic device package.

The term “package substrate” is used herein. A package substrate is a substrate arranged to receive a semiconductor die and in the illustrated examples, other components, and to support the semiconductor die in a completed semiconductor device package. Package substrates useful with the arrangements include conductive lead frames, molded interconnect substrates (MIS), partially etched lead frames, pre-molded lead frames, embedded trace substrates (ETS), and multilayer package substrates. In example arrangements, semiconductor dies and passive components are formed integrated together in an integrated system device, the integrated system device is then mounted to a package substrate, such as a leadframe, and arranged for packaging. The integrated system device can be mounted and packaged with fewer steps and with higher reliability than in a prior approach where semiconductor dies are individually mounted to a multilayer package substrate containing routing conductors, and a passive element, which is also separately mounted to a package substrate. The various solder connections needed among different elements in multiple solder reflow processes used in the prior approach can create failures in thermal cycling, resulting in possible solder joint failures and package cracking defects due to delamination.

The term “trace level conductor” is used herein. As used herein, a trace level conductor is a layer of patterned conductor material which, when a device is oriented with a top surface in a horizontal plane, forms a horizontal conductor layer. Since the term “horizontal” is relative to the position of the device, the term “trace level conductor” is used herein. In a completed microelectronic device package of the arrangements that is placed with a top surface in a horizontal plane, the trace level conductors will lie in horizontal layers and be spaced from one another by dielectric material.

The term “connection level conductor” is used herein. As used herein a connection level conductor is a layer of patterned conductor material that extends through a dielectric layer between layers of trace level conductors. In a completed microelectronic device package of the arrangements that is placed with a top surface in a horizontal plane, the connection level conductors will extend vertically through layers of dielectric materials between layers of trace level conductors and provide electrical coupling of the trace level conductors. Using the trace level conductors and the connection level conductors, routing paths through a multilayer conductor structure can be formed.

The term “via” is used herein. As used herein, a via includes conductor material deposited in an opening in a dielectric layer to form an electrical connection to a conductor underlying the dielectric layer. Vias are formed by drilling an opening in a dielectric layer and then depositing conductor material in the opening. Although vias function in a fashion like the connection level conductors, the process for forming vias limits the shapes and sizes of the vias. In contrast, the additive build-up processes used to form connection level conductors of the arrangements allow arbitrary shapes and sizes to be formed.

The term “integrated system device” is used herein. As used herein, an integrated system device includes at least one semiconductor die embedded in dielectric material, with a multilayer conductor structure formed over and coupled to the at least one semiconductor die. Conductive lands for mounting the integrated system device are formed using the conductor material and are exposed from the dielectric material on a surface. These conductive lands can be used to mount the integrated system device to a package substrate such as a leadframe.

The term “package substrate” is used herein. A package substrate is a substrate arranged for mounting semiconductor dies or components and having conductors to couple to the semiconductor dies or components. In example arrangements, a leadframe is used as a package substrate, the leadframe provides leads that are arranged for coupling to semiconductor dies. The term “multilayer package substrate” is used herein. A multilayer package substrate is a substrate that has multiple conductor layers in dielectric material including trace level conductors, and which has connection level conductors extending through the dielectric material between the trace level conductor layers. A “routable leadframe” (RLF) is an example of a multilayer package substrate and the term RLF can be used. In an example arrangement, an additive manufacturing process is performed by plating a patterned trace level conductor and then covering the trace level conductor with a layer of dielectric material. Grinding or thinning can be performed on the dielectric material to expose portions of the top surface of the layer of conductors from the dielectric material. Additional plating layers can be formed to add additional levels of trace level conductors, at least some of which are trace level conductor layers that are coupled to other trace level conductor layers in the dielectric materials by connection level conductors, and additional dielectric material can be deposited at each layer and can cover the conductors. By using an additive build-up manufacturing approach, and by performing multiple plating steps, multiple dielectric formation steps, and multiple grinding steps, a multilayer conductor and dielectric structure is formed in an integrated system device with an arbitrary number of trace level conductor layers and connection level conductor layers between and coupling portions of the trace level conductor layers. In an example arrangement, passive components including coils and transformers can be formed. In the arrangements, an integrated system device is formed by integrating at least one semiconductor die in the multilayer package substrate structure. The integrated system device is arranged to be mounted to a package substrate for use in a microelectronic device package. Use of the arrangements simplifies the packaging process and increases reliability of the semiconductor device package.

In an example integrated system device used in an arrangement, copper, gold, or tungsten conductors are formed by plating, and a thermoset material is used as the dielectric material. Connector level conductors are formed between trace level conductor layers and can be of arbitrary shapes and sizes. The conductors can be arranged to form rails and pads to couple layers of trace level conductors with low resistance for power applications and for carrying high current signals. In sharp contrast to the filled vias used in circuit boards and in other substrate structures, the connection level conductors extending through the dielectric material to couple trace level conductors are not formed by filling holes drilled through dielectric material, which are limited in size and shape. Instead, in the arrangements, an additive build-up approach forms the connection level conductors, which are plated during the additive build-up manufacturing process, and thus the connection level conductors can vary in shapes and sizes. Multiple layers of trace level conductors and of connection level conductors can be patterned as stacked conductors extending through the dielectric material, and these stacked conductors can form arbitrary shapes. In the arrangements, the integrated system device is formed by including semiconductor dies and passive components in the multilayer package substrate, the conductors formed coupled to the bond pads of the semiconductor dies, and portions of the conductors forming passive components such as a primary coil and a secondary coil of a transformer arranged to form an isolation device.

In packaging microelectronic and semiconductor devices, mold compound may be used to partially cover a package substrate, to cover an integrated system device, to cover passive components, to cover a semiconductor die, and to cover the electrical connections made to the package substrate. This molding process can be referred to as an “encapsulation” process, although some portions of the package substrates are not covered in the mold compound during encapsulation, for example terminals and leads are exposed from the mold compound to enable electrical connections to the packaged device. Encapsulation is often a compressive molding process, where thermoset mold compound such as resin epoxy can be used. A room temperature solid or powdered mold compound can be heated to a liquid state and then molding can be performed by pressing the liquid mold compound into a mold through runners or channels. Transfer molding can be used. Unit molds shaped to surround an individual device may be used, or block molding may be used, to form multiple packages simultaneously for several devices from mold compound. The devices to be molded can be provided in an array or matrix of several, hundreds or even thousands of devices in rows and columns that are then molded contemporaneously.

After the molding process is complete, the individual microelectronic device packages are cut apart from each other in a sawing operation. A mechanical saw can be used to cut through the mold compound and package substrate material in saw streets formed between the devices. Portions of the package substrate leads are exposed from the mold compound package to form terminals for the microelectronic device packages. In the example arrangements, a leadframe is used as a package substrate.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

In the arrangements, semiconductor dies, such as drivers and receivers for coils, can be integrated with passive components, such as the coils, to form an integrated system device. The semiconductor dies can be coupled to the passive components by conductors. In an example arrangement, a pair of semiconductor dies, isolated from one another, are coupled to a primary coil and a secondary coil that are also electrically isolated from one another, but which are positioned to inductively couple. The primary coil and the secondary coil are formed by patterning the conductors within the multilayer package substrate of the integrated system device, for example planar coils can be formed that are spaced from one another by the dielectric material of the multilayer package substrate. In operation, current can be delivered from the primary coil to the secondary coil by inductive coupling of the coils, that is, the integrated system device includes a transformer. In additional example arrangements multiple passive components can be used. In additional example arrangements, the integrated system device can have two or more trace level conductor layers, and the integrated system device can be used to form other systems.

Use of the arrangements to integrate the passive components and the semiconductor dies in an integrated system device allows for a microelectronic device package that is simple to assemble in a packaging process, and with increased reliability over prior packaging approaches.

In a particular example arrangement, a transformer is formed within an integrated system device with multiple trace level conductor layers. The transformer has a primary coil and a secondary coil. A first semiconductor die is integrated into the integrated system device and coupled to the primary coil, while a second semiconductor die is integrated into the integrated system device and coupled to the secondary coil. The integrated system device is arranged to be used with a first voltage domain including the primary coil that is isolated from a second voltage domain including the secondary coil. The dielectric material used in forming the integrated system device and the spacing between conductors provides high voltage isolation for power applications. In an example the isolation voltage can reach up to 3.5 Kilovolts.

The integrated system device of the arrangements is then mounted to a to a package substrate. In particular examples the package substrate is a leadframe. The leadframe includes a first set of conductive leads for the first voltage domain spaced from a second set of conductive leads for the second voltage domain. The first set of leads is arranged one side of the package substrate, and the second set of leads is arranged on an opposite side of the package substrate, for example a leadframe, to provide sufficient physical spacing for isolation between the voltage domains. A microelectronic device package is formed in a transfer molding process. In this way power can be transferred between the two voltage domains, for example a DC-DC converter can be formed by using a leadframe with sufficient spacing between the first set of voltage leads and the second set of voltage leads, and by sizing the package body to provide a needed clearance distance (distance between exposed leads in air) and a required creepage distance (distance over the package body between exposed leads) to prevent unwanted current leakage. A robust microelectronic device package with isolation is provided by use of the arrangements.

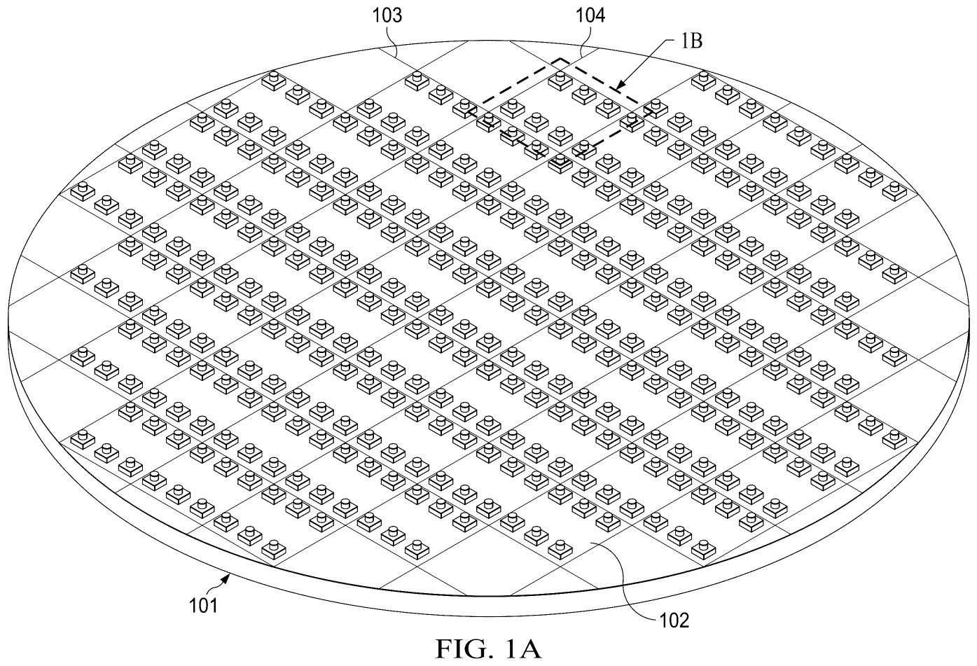

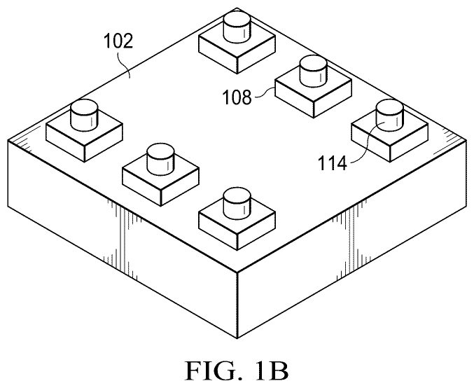

FIGS. 1A and 1B illustrate, in two projection views, a semiconductor wafer having semiconductor die devices formed on it that are configured for flip chip mounting, and an individual semiconductor die for flip-chip mounting, respectively. In FIG. 1A, a semiconductor wafer 101 is shown with an array of semiconductor dies 102 formed in rows and columns on a surface. The semiconductor dies 102 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another, and which run in parallel groups across the semiconductor wafer 101, separate the rows and columns of the completed semiconductor dies 102, and the scribe lanes provide areas for dicing the wafer 101 to separate the semiconductor dies 102 from one another.

FIG. 1B illustrates a single semiconductor die 102 taken from semiconductor wafer 101. Semiconductor die 102 includes bond pads 108, which are conductive pads that are electrically coupled to devices (not shown) formed in the semiconductor die 102. Conductive post connects 114 are shown extending away from a proximate end on the bond pads 108 on the surface of semiconductor die 102 to a distal end. The conductive post connects 114 can be formed by electroless plating or by electroplating. In an example, the conductive post connects 114 are copper. In flip-chip type packages, the conductive post connects may have solder bumps on the distal ends and are sometimes referred to as “copper pillar bumps.” However, in the arrangements described here, the solder bumps are not needed and so the wafer 101 has conductive post connects, such as copper post connects, extending from the bond pads, but the solder deposition steps are omitted. Copper pillars can be formed by sputtering a seed layer over the surface of the semiconductor wafer 101, forming a photoresist layer over the seed layer, using photolithography to expose seed layer over the bond pads 108 in openings in the layer of photoresist, and plating copper to form conductive post connects 114 on the bond pads. Other conductive materials can be used for the conductive post connects in an electroplating or electroless plating operation, including gold, silver, nickel, palladium, or tin, for example. Not shown for clarity of illustration are under-bump metallization (UBM) portions which can be formed over the bond pads 108 to improve plating and adhesion between the conductive post connects 114 and the bond pads 108. After the plating operations, the photoresist is then stripped, and the excess seed layer is etched from the surface of the wafer. Polyimide (PI) (not shown for simplicity of illustration) or other dielectric material can be applied between the conductive post connects to protect the semiconductor die 102 and the conductive post connects 114. The semiconductor dies 102 are then separated by dicing, or are singulated, using the scribe lanes 103, 104 (see FIG. 1A).

In an alternative arrangement, semiconductor dies can be used without forming the conductive post connects. In this approach, filled vias are formed in the multilayer package substrate and contact the bond pads, and the routing layers of the multilayer package substrate are then formed over the filled vias to complete the multilayer package substrate. Either of these approaches can be used with the arrangements.

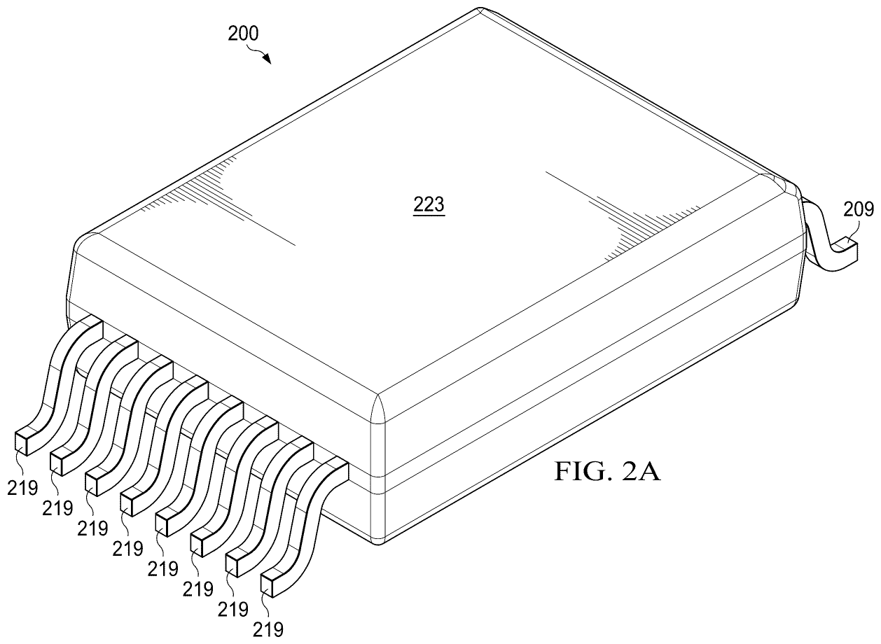

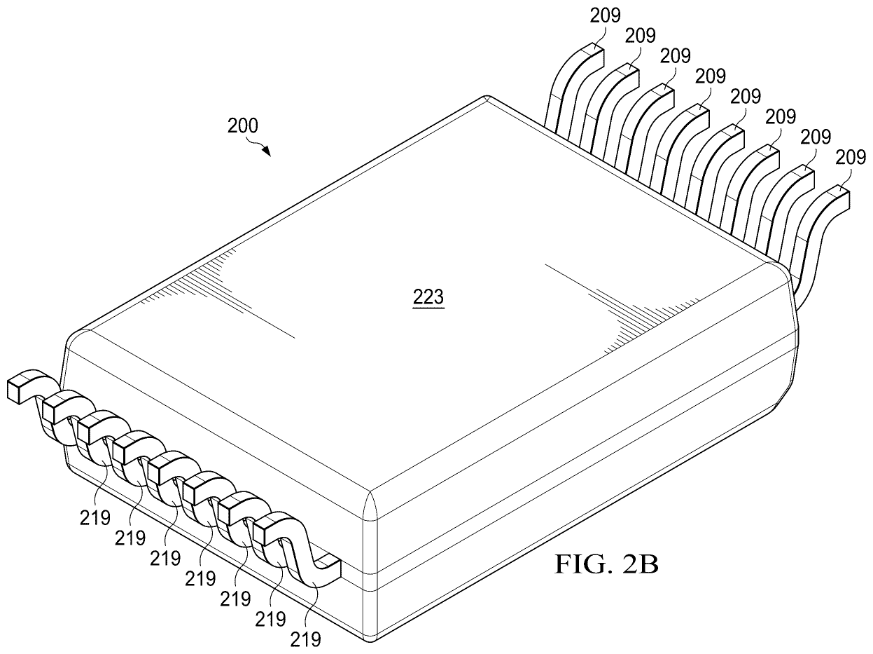

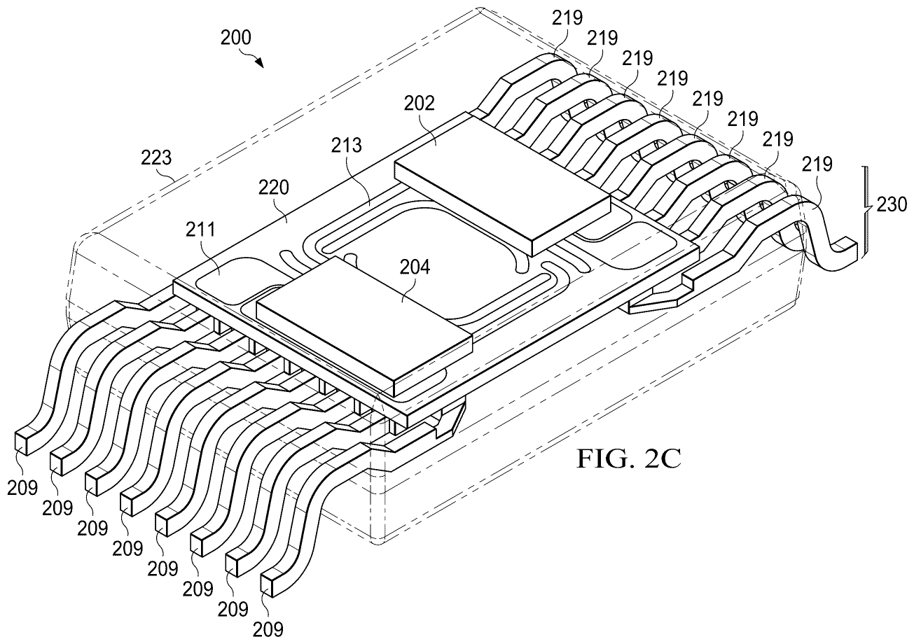

FIGS. 2A-2B illustrate, in projection views from a top view and a bottom view, respectively, a microelectronic device package that can be used with an arrangement. In FIG. 2A, the microelectronic device package 200 is shown in a top side projection view. In the illustrated example, the microelectronic device package 200 is a small outline package (SOP). One type of SOP is a small outline integrated circuit (SOIC) package. The body of the microelectronic device package 200 is formed by mold compound 223. Leads 209 are shown extending from a middle portion of the mold compound 223, and the leads are shaped in a “gull wing” shape for use in surface mounting to a system board, for example using processes for surface mounting technology (SMT). The leads 209 extend away from the package body and are shaped to form “feet” at the outward ends for surface mounting. Other lead shapes can be used. An advantage of gull wing shaped leads is that the leads allow some slight movement, for example due to movement of the board or a device during assembly, or due to thermal dissipation in operation, without causing a solder joint failure, increasing board level reliability (BLR).

FIG. 2B illustrates the microelectronic device package 200 from a bottom side view. In FIG. 2B, the first set of leads 209 is spaced from a second set of leads 219. Mold compound 223 forms a body for the microelectronic device package 200. Leads 209 can be arranged to be coupled to a first voltage domain, while leads 219 are arranged to be coupled to a second voltage domain electrically isolated from the first voltage domain.

FIG. 2C illustrates, in a projection view from a top side, a microelectronic device package 200 that includes elements that can be used in an arrangement. In FIG. 2C, a package body formed by mold compound 223 is shown as partially transparent for use in describing the other elements. A leadframe 230 is shown with the first set of leads 209 arranged for a first voltage domain, which can be an input voltage, and a second set of leads 219 arranged for a second voltage domain, which can be an output voltage. In one example application, a DC/DC converter is implemented using the microelectronic device package 200. The first voltage domain and the second voltage domain have isolated grounds, and therefore the leads coupled to the first voltage domain, and the leads coupled to the second voltage domain, need to be electrically isolated. In the microelectronic device package 200, galvanic isolation is used. An integrated system device 220 includes a transformer with a primary coil 211 and a secondary coil 213. The primary coil 211 and the secondary coil 213 are spaced apart and electrically isolated by dielectric material that forms the integrated system device 220, for example Ajinomoto build-up film (ABF) can be used. Using inductive coupling, energy can be transferred from the first voltage domain to the second voltage domain. The integrated system device 220 includes a first semiconductor die 204 that can be coupled to the primary coil 211 by conductors in the dielectric, and a second semiconductor die 202 can be coupled to the secondary coil 213 by conductors formed in the dielectric material of the integrated system device 220. The mold compound 223 covers and protects the elements including portions of the leads 209 and portions of the leads 219 and provides a minimum spacing between the leads of different voltage domains (to provide a minimum clearance distance to prevent open air coupling) and a creepage distance, to prevent current from leaking by traversing the package body between leads of the different voltage domains.

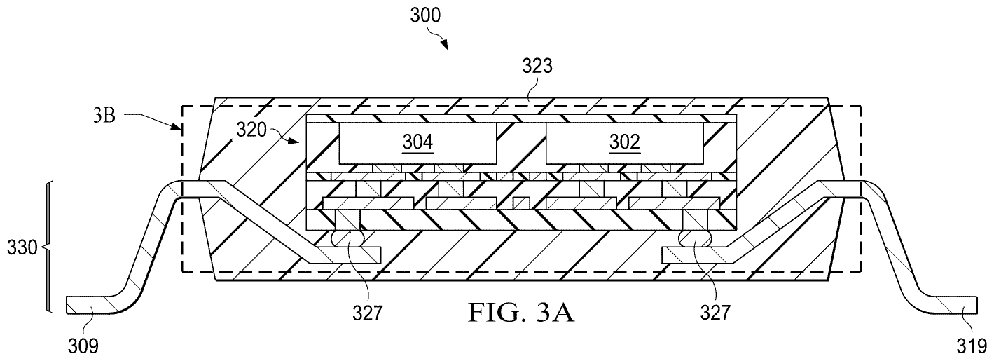

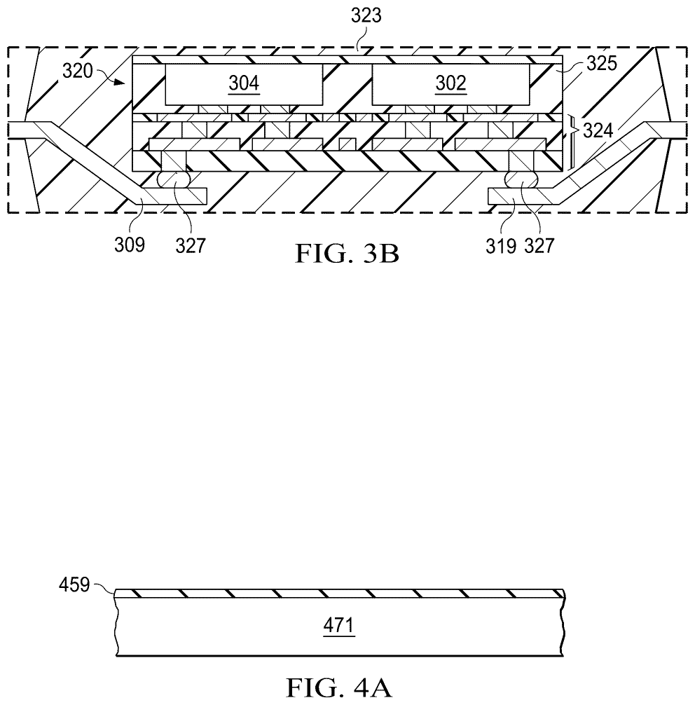

FIG. 3A illustrates, in a cross-sectional view, a microelectronic device package 300 of an example arrangement for an isolated package with an integrated system device 320. In FIG. 3A, the microelectronic device package 300 includes a package body of a mold compound 323, and a package substrate, here a leadframe 330. The example leadframe 330 is a downset leadframe, with leads extending into the middle of the package body and then angled downwards to provide a device mounting surface in a position lower than the middle of the package body, increasing the vertical space on the device side of the leads for the components mounted inside the package body. An integrated system device 320 is shown mounted to the device side of a first set of conductive leads 309 on one side of the package substrate for a first voltage domain and mounted to a second set of conductive leads 319 on an opposite side of the package substrate 330 for a second voltage domain. In an example, the first voltage domain can be an input voltage of about 6-18 Volts, and the second voltage domain can be an output voltage of about 10-25 Volts. The integrated system device 320 thus implements a DC/DC converter that can be arranged as a step-up or step-down DC-DC voltage converter. Semiconductor dies and coils are provided within the integrated system device 320 as is further detailed in FIG. 3B and described below. The integrated system device 320 is implemented as a solder mountable component and is shown mounted to the leads 309, 319 of leadframe 330 by solder joints 327, which can be formed in a thermal reflow process from solder placed on the leadframe. By providing the integrated system device 320 as a complete component, assembly of the microelectronic device package 300 is made simpler (when compared to microelectronic device packages of prior approaches made without use of the arrangements, where the semiconductor dies are assembled to a laminate or substrate carrying the passive components, such as the coils, and the substrate is subsequently mounted to the leadframe using solder, so that several separate thermal reflow solder operations are needed; increasing the cost, the possibility of voids and other solder defects). Use of the arrangements increases reliability and simplifies packaging processes, lowering costs of the final package.

In FIG. 3B, the details of the integrated system device 320 are shown in a close-up cross-sectional view of the microelectronic device package 300. The integrated system device 320 is formed of multiple layers of trace level conductors 324 spaced by a dielectric 325, and which can be joined by connection level conductors extending through the dielectric 325. The trace level conductors 324 can form routing between the first semiconductor die 304 and the leads 309 for the first voltage domain and can form a passive element such as a coil. The trace level conductors 324 can also couple the second semiconductor die 302 to the leads 319 of the second voltage domain and can form another passive component coupled to the second semiconductor die 302, such as another coil. In an application where a microelectronic device package of the arrangements including an integrated system device can be used, a DC to DC converter can be implemented with a primary side controller circuit and a full bridge circuit arranged in a first semiconductor die, and a secondary side controller circuit and a rectifier arranged in a second semiconductor die, the first semiconductor die and the primary coil electrically isolated from the second semiconductor die and the secondary coil. A feedback circuit in the second semiconductor die can monitor an output voltage that is derived from an input voltage by use of a switched power circuit in the first semiconductor die to apply current to the primary coil. Voltage regulation is achieved by the feedback circuit which communicates to the controller in the first semiconductor circuit using isolated signals across the isolation barrier between the coils. Other power circuits using coils and transformers can be implemented using a microelectronic device package of the arrangements.

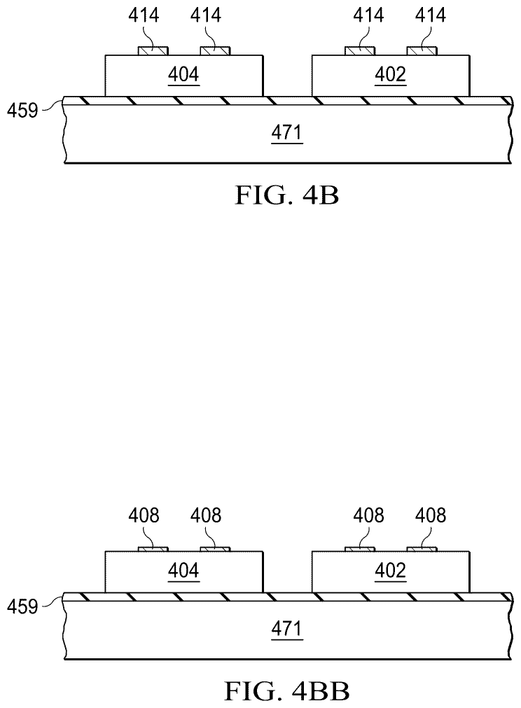

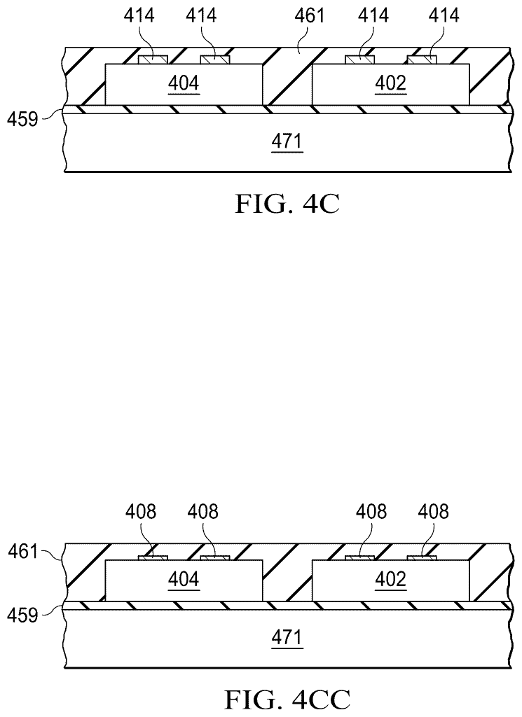

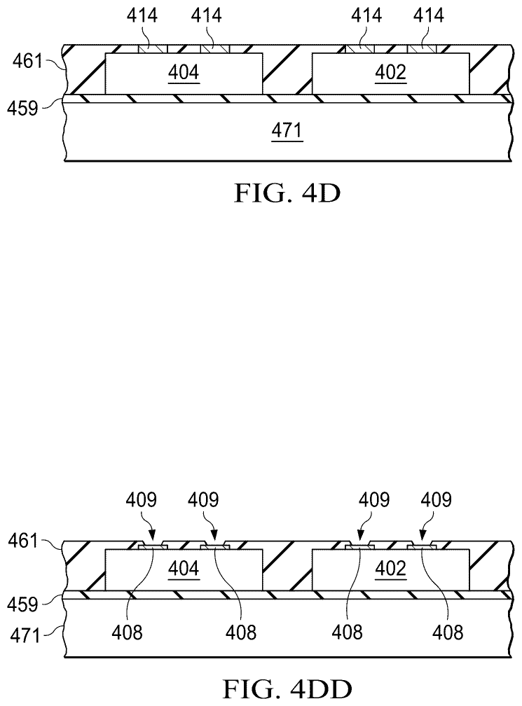

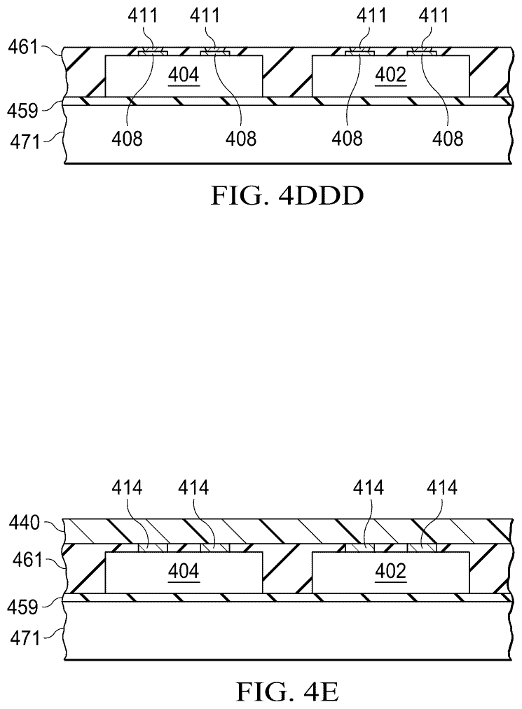

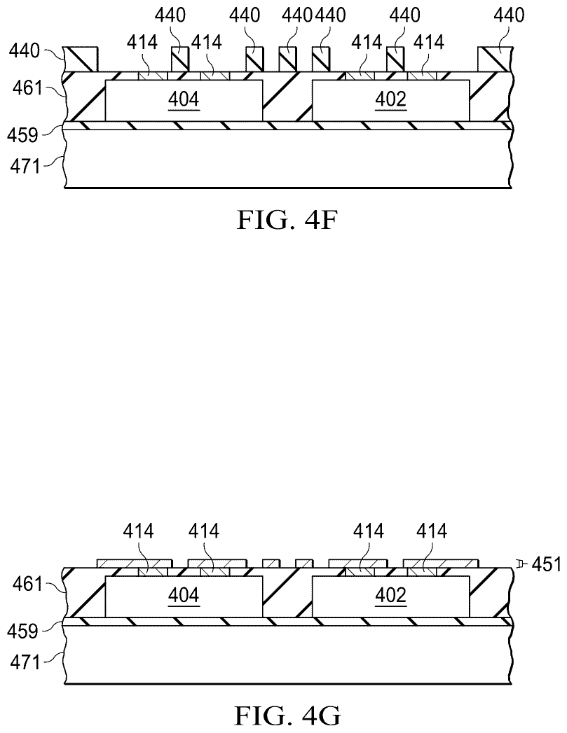

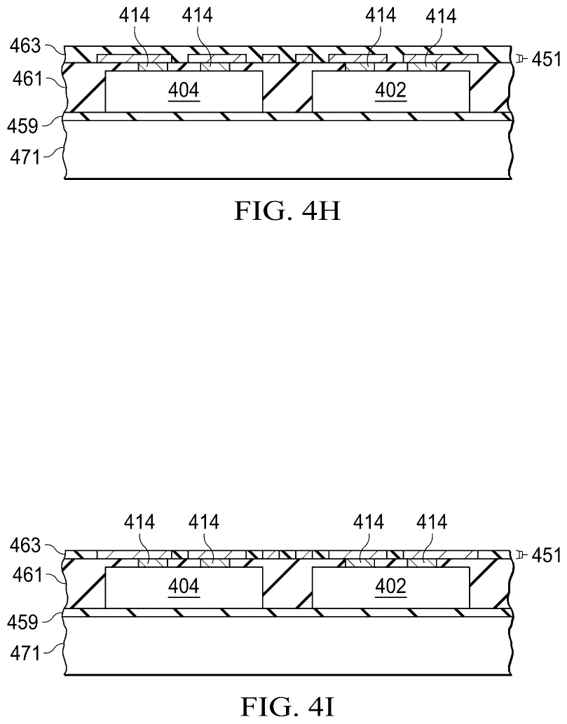

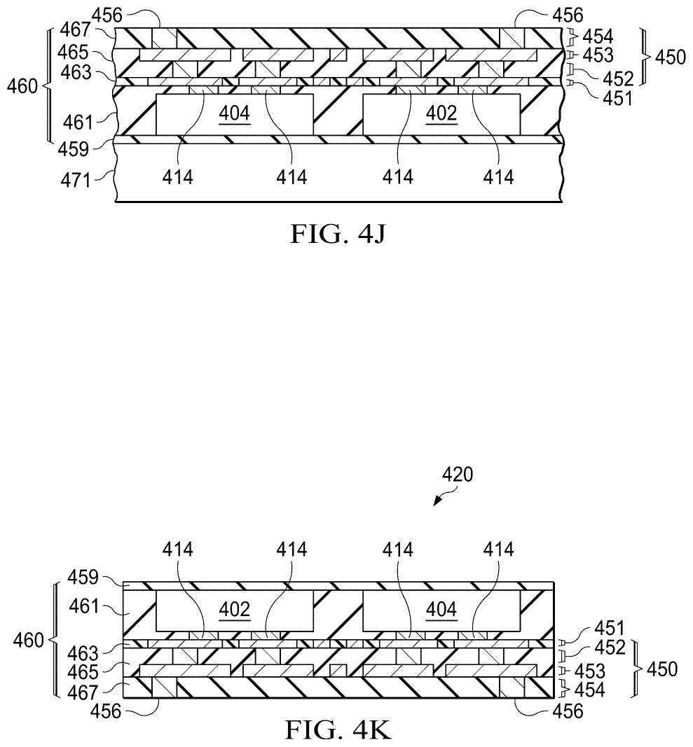

In the arrangements, in an example process the integrated system device 320 is formed using an additive build-up manufacturing approach to build multiple layers of conductors and dielectric material, and including the semiconductor dies embedded in the dielectric material. The conductors and dielectric are formed in layers, using a repeated sequence of conductor plating, dielectric deposition, and grinding to form each trace level conductor layer. Plating and photolithography are used to form the connection level conductors between the layers of trace levels conductors, and to deposit additional dielectric for each layer of trace level conductor, in sequential steps. By using additive build-up manufacturing to form the integrated system device 320, arbitrary shapes can be formed of the conductor material (in contrast to prior approach laminate structures where filled vias are used, which are limited in shapes and sizes.) The number of layers of trace level conductors formed can be increased simply by repeating the additive build-up sequence. As is further described below, dielectric 325 can be formed of a build-up film in a lamination process, or alternatively the dielectric can be formed of a thermoset or thermoplastic material such as a mold compound, for example. The dielectric 325 provides the electrical isolation needed between conductors and protects the elements. The dielectric 325 can be selected depending on the spacing of the elements to provide the isolation needed, because dissimilar materials can be used having different dielectric properties. An example method for forming the integrated system device 320 is described below and selected steps are shown in FIGS. 4A-4B, 4BB, 4C, 4CC, 4D, 4DD, 4DDD, 4E-4K.

In FIG. 4A, a first step of an example method for forming an integrated system device similar to integrated system device 320 is shown. In FIG. 4A, a first dielectric layer 459 is shown formed on carrier 471. The carrier provides support to the elements during processing and the completed structure will be removed from the carrier 471 which can, for example, stainless steel, glass, or a semiconductor material. The carrier 471 can be, in an example process, cleaned and reused. Alternatively, the carrier 471 can be discarded at the end of the process.

In one example process for forming an integrated system device useful in the arrangements, thermoset epoxy resin mold compound is used as the dielectric layer 459. In another approach, a thermoset film such as Ajinomoto build-up film (ABF) commercially available from Ajinomoto Fine-Techno Co., Inc. of Tokyo, Japan is used. In the method, regardless of whether mold compound or ABF is used, a build-up manufacturing process is used, so that multiple layers of dielectric are formed, with layers of trace level conductors formed spaced by the dielectric material, and connection level conductors formed extending through the dielectric between the trace level conductor layers, the trace level conductors and the connection level conductors all formed in plating processes. By using an additive build-up approach, arbitrary shapes can be formed in the trace level conductor layers and in the connection level conductor layers, for example vertical walls, tanks, or shields can be formed, planar coils can be formed, low resistance thick conductor layers can be formed for carrying high currents, all formed without the restrictions on shape imposed by laminate substrate structures with filled vias. Ground planes and conductive sheets can be formed.

To form the dielectric layer 459, in one example process, powdered epoxy resin mold compound is used in a panel molding tool. The powdered epoxy resin mold compound is a solid powder at room temperature. After the mold is filled with the powdered mold compound, the tool raises the powdered mold compound to an elevated temperature to cause it to transition to a liquid state. As the mold compound in the panel molding tool becomes a liquid, compression is used to ensure there are no voids or areas of incomplete fill. As the liquid mold compound is continued to be heated, it sets to a solid state, as the epoxy resin mold compound is a thermoset material. After the mold compound sets, a post mold cure in an oven completes dielectric layer 459 by curing the mold compound to harden it.

The process for forming layers of dielectric using solid powdered mold compound described above can be repeated for each dielectric layer, as is further described below.

In an alternative approach using ABF, the dielectric layer 459 can be formed using ABF films. In an example process, the film is positioned in the mold tool. The film is heated to soften it so that the film conforms to the mold tool, without voids. To further ensure the ABF film conforms, a vacuum can be used to remove air beneath the film. The film is a thermoset epoxy resin and becomes a solid. A post mold cure can then be used to further harden the layer to form dielectric layer 459.

In an arrangement using ABF for the dielectric layers, these steps are repeated for each dielectric layer formed. To increase thickness, layers of the ABF film can be stacked and cured to form a thicker dielectric layer.

At FIG. 4B, the dielectric layer 459 is shown with a first semiconductor die 404 and a second semiconductor die 402 mounted to the dielectric layer 459. A die attach film, or a die attach epoxy (not shown for simplicity of illustration) can be used to attach the semiconductor dies 402, 404 to the dielectric layer 459. In the illustrated example, the semiconductor dies 402, 404 have conductive post connects 414, which can be copper pillars, for example, on a device side surface. Gold pillars can be used.

FIG. 4BB illustrates an alternative example where the semiconductor dies 402, 404 do not have conductive post connects, so that the bond pads 408 are used to couple to other conductors in the arrangements. In FIG. 4BB, semiconductor dies 402, 404 are shown mounted to the dielectric layer 459 with the bond pads 408 facing upwards (as oriented in FIG. 4BB) for further processing.

At FIG. 4C, the elements of FIG. 4B are shown after an additional processing step. A second dielectric layer 461 is shown formed over the semiconductor dies 402, 404 and covering the conductive post connects 414. In an example using powdered thermoset epoxy resin mold compound, mold compound is placed in a mold tool, for example the mold compound is a powder at room temperature. As described above, the powdered mold compound is heated to a liquid state and compressed and sets to a solid state. The mold compound is then cured by a post mold thermal cure and hardens. The carrier 471 supports the elements including the dielectric layer 459 previously formed, and the semiconductor dies 402 and 404. The cured mold compound forms a solid dielectric layer 461.

FIG. 4CC illustrates, in a similar cross-sectional view, the elements of FIG. 4BB after an additional processing step forms dielectric layer 461 over the bond pads 408 of semiconductor dies 402, 404 of FIG. 4BB. The process used depends on the dielectric material chosen, for the powdered mold compound, the process is as described above, the powdered solid mold compound is dispensed into a mold over the semiconductor dies 402, 404, the mold tool heats the powdered mold compound to a liquid state, compression is applied to ensure proper fill and to reduce voids in the liquid, the liquid mold compound sets, and after the molding, a post mold cure hardens the liquid mold compound to a hard solid state. If ABF is used, again the film is applied over the elements, the ABF is heated to soften the film, vacuum is used to ensure the film conforms to the elements beneath the film without voids, and the film sets. Another post mold cure process hardens the ABF film to a solid dielectric.

FIG. 4D illustrates, in another cross-sectional view, the elements of FIG. 4C after an additional process step. In FIG. 4D, the conductive post connects 414 of the semiconductor dies 402, 404 are exposed from the dielectric layer 461 in a grinding operation. For example, a mechanical grinding operation can be used, or a chemical-mechanical polishing operation can be used. The conductive post connects 414, which can be copper pillars, are then ready for plating processes to form conductor layers of the integrated system device.

In the alternative approach using the semiconductor dies with bond pads 408 of FIG. 4BB and 4CC, without the conductive post connects, as shown in FIG. 4DD in another cross-sectional view, via openings 409 are opened by a drilling operation to expose the bond pads 408 from the dielectric layer 461. In an example process, a laser drill can be used. At FIG. 4DDD, the vias 411 are shown after a via filling process, such as depositing a seed layer and electroplating, is used to form the vias 411 in the via openings (see 409 in FIG. 4DD). After a planarization step, the arrangement in FIG. 4DDD can be processed in the same manner as the arrangement in FIG. 4D for the remaining steps described below to form the build-up layers of conductors and dielectric over the semiconductor dies 402, 404. In the illustrations shown in the cross-sections in FIGS. 4E-4K, the processes shown are for the conductive post connect arrangements as shown in FIG. 4D, but the process used for the bond pad arrangement of FIG. 4DDD would be the same and are not illustrated here, to avoid repetition.

FIG. 4E illustrates, in a further cross-sectional view, the elements of FIG. 4D, after additional processing. In FIG. 4E, a layer of photoresist 440 is shown deposited over the dielectric layer 461 and the conductive post connects 414. Depositing photoresist 440 begins a process for forming conductor layers. Not shown in FIG. 4E is a sputtered seed layer which can be formed over the elements in preparation for plating processes. In some examples, the conductive post connects 414 can be copper pillars, and the ends of the copper pillars can be used in lieu of a seed layer for plating additional copper. In other examples, where patterns are needed away from the conductive post connects 414, a seed layer can be sputtered over the elements to provide the needed material for plating.

FIG. 4F illustrates, in another cross-sectional view, the elements of FIG. 4E after additional processing. In FIG. 4F, the photoresist layer 440, which can be a dry photoresist layer, is shown after photolithography patterns the layer to form a first conductor layer. Openings are formed in the photoresist layer 440 corresponding to conductive post connects 414 in preparation for plating.

FIG. 4G illustrates, in a further cross-sectional view, the elements of FIG. 4F after a plating process. Trace level conductor layer 451 is formed using the photoresist 440 in an electroless or electroplating process. Following the plating process, the photoresist 440 (see FIG. 4F) is removed by a photoresist strip process, The trace level conductor layer 451 forms a first trace level conductor layer, at least a portion of the conductors in trace level conductor layer 451 are coupled to either semiconductor die 404 or semiconductor die 402.

FIG. 4H illustrates, in another cross-sectional view, the elements of FIG. 4G after additional processing. In FIG. 4H an additional dielectric layer 463 is deposited over the trace level conductor layer 451. This dielectric layer can be of the same material, for example formed by use of powdered epoxy resin mold compound or by depositing ABF, as described above for forming the dielectric layers 459, 461. In an additional alternative approach, different dielectric materials can be used for different dielectric layers.

FIG. 4I illustrates, in a further cross-sectional view, the first trace level conductor layer 451 exposed by grinding the dielectric layer 463. Additional photoresist deposition, patterning, plating steps, resist strip, and dielectric deposition steps can be used to form layers of connection level conductors between layers of trace level conductors to form two, three or more trace level conductor layers and corresponding connection level conductor layers extending through the dielectric layers.

FIG. 4J illustrates in a further cross sectional view the elements shown in FIG. 4I, after repeated dielectric and conductor deposition processes complete an arrangement with two trace level conductor layers. In FIG. 4J, the semiconductor dies 402, 404 are shown on dielectric layer 459, and covered by dielectric layer 461. The conductive post connects 414 extending from the semiconductor dies 402, 404 are coupled to the first trace level conductor layer 451, which lies in dielectric layer 463, along with the first connection level conductor layer 452. A second trace level conductor layer 453 is formed in a dielectric layer 465, along with the second connection level conductor layer 454. More trace level conductor layers and connection level conductor layers can be formed using the photolithography, patterning, plating, dielectric deposition and grinding sequence to add more layers in the additive build-up process, as needed. The dielectric layers 459, 461, 463, 465 and 467 form a block of dielectric material 460, and can be formed of thermoset mold compound, or of ABF, for example, depending on the isolation requirements and the needed dielectric characteristics to meet the isolation requirements. Conductive lands 456 are shown formed from a connection level conductor layer 454, alternatively conductive lands 456 can be formed from a trace level conductor layer, the conductive lands 456 are exposed from the dielectric material to form conductive mounts for the integrated system device.

FIG. 4K illustrates an integrated system device 420 formed using the steps described above to embed the semiconductor dies 402, 404 in a block of dielectric material 460 made of successive dielectric layers 459, 461, 463, 465 and 467, and incorporating trace level conductor layers 451, 453 and connection level conductor layers 452, 454 in the integrated system device 420. In an example arrangement, the trace level conductor layers 451, 453 can form planar coils, such as a primary coil and a secondary coil of a transformer. The first semiconductor die 404 can be a primary coil controller that includes a bridge of transistor devices which supplies a current from a voltage input to the primary coil using pulse width modulation to periodically apply current to the primary coil. Using inductive coupling across the isolation barrier formed of the dielectric material, a corresponding current is induced in the secondary coil. The second semiconductor die 402 can be a secondary coil controller that includes a rectifier to rectify the switching current and supply the current at a voltage output to a load, with a feedback controller to monitor the output voltage and transmit feedback signals to the primary coil controller. A DC-to-DC converter can be formed using the integrated system device 420. Other isolated power circuits can be formed using a single semiconductor die and a pair of coils, or a single coil, or a transformer with a pair of coils and two or more semiconductor dies can be used. Sensors can be formed to improve performance, such as temperature, overcurrent, undercurrent, or open detectors that can be integrated into the semiconductor dies 402, 404 or into additional semiconductor dies that can be embedded in the integrated system device 420. Conductive lands 456 are shown arranged for mounting the integrated system device 420.

The integrated system device 420 is a unit that can be provided in an array of rows and columns in a panel formed using the processes described above. The panel can be supplied intact with tens, hundreds or even thousands of integrated system devices such as 420 in rows and columns spaced by saw streets between the rows and columns. Alternatively, the integrated system devices can be singulated and supplied as individual units such as integrated system device 420 in FIG. 4K. The individual integrated system device units can be used with pick and place tools in a packaging process to be mounted to leadframes or other package substrates for packaging, as is further described below.

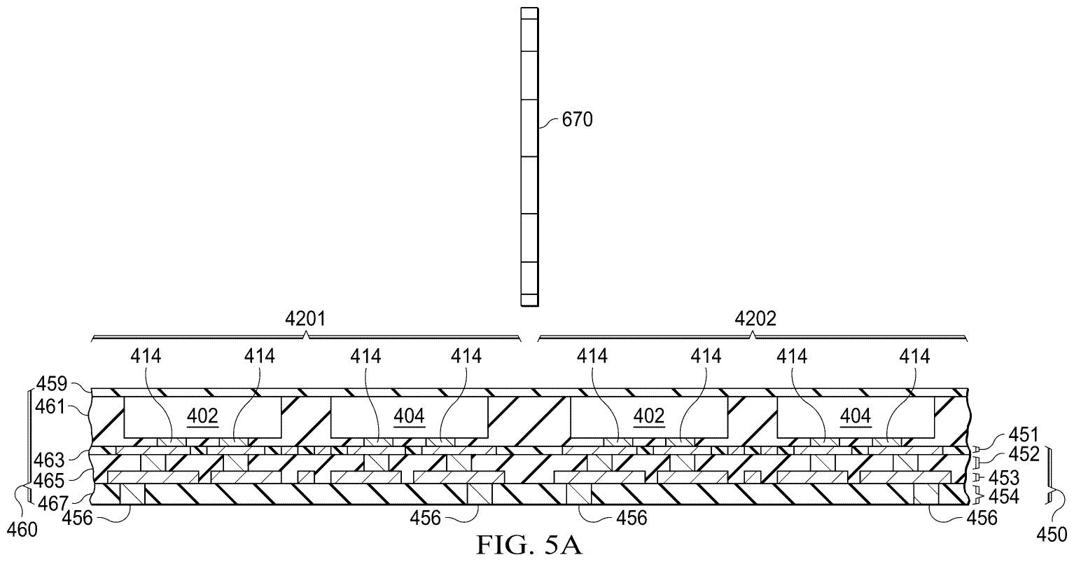

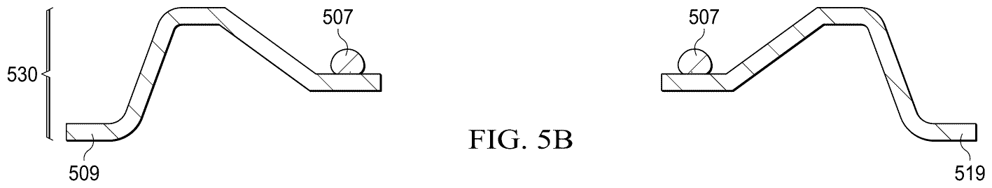

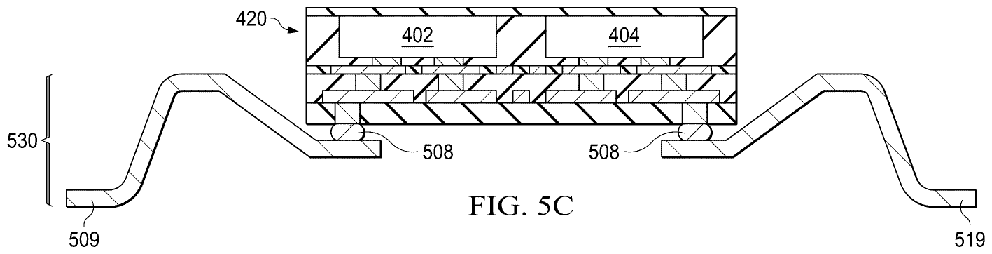

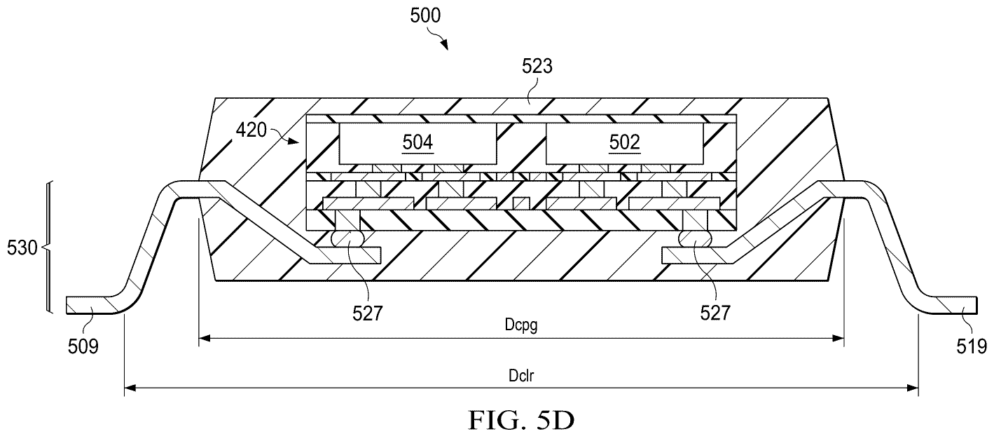

FIGS. 5A-5C illustrate, in a series of selected steps shown in cross-sectional views, an assembly method for a microelectronic device package of an arrangement.

In FIG. 5A, a portion of a panel of integrated system devices is shown in a partial cross-sectional view, with replicated integrated system devices 4201, 4202 shown next to each other, each is a copy of integrated system device 420 (see 420 in FIG. 4K). In a practical example, the integrated system devices 4201, 4202 can be provided in a strip or array of replicated integrated system devices manufactured simultaneously, to increase throughput and reduce unit costs. In FIG. 5A, a singulation step is shown. A rotating saw 670 is shown traversing a saw street between integrated system devices 4201, 4202 to singulate individual integrated system devices (see 420 in FIG. 4K) for use in the arrangements.

In FIG. 5B, leadframe 530 is shown arranged for mounting an integrated system device of the arrangements. In FIG. 5B, a downset leadframe is shown. The downset leadframe can be used to form an SOIC, wide SOIC, or another small outline package (SOP), for example. Lead 509 may be isolated from the lead 519, so that lead 509 can be for signals or power connections in a first voltage domain, for example for an input voltage. The lead 519 may be isolated from lead 509 and can be arranged for signals or power connections in a second voltage domain, for example for an output voltage for delivering power to a load. Solder balls 507 are placed on the internal ends of leads 509, 519 and are arranged for mounting an integrated system device of the arrangements (see, for example, integrated system device 420 in FIG. 4K).

In FIG. 5B, a single leadframe 530 is shown. In a practical application, unit leadframes are provided in a strip, array, or grid, with multiple unit leadframes placed in a row with saw streets of the leadframe material between the unit leadframes, for use in a gang assembly method to increase throughput. In another alternative the unit leadframes can be arranged in a grid or array in rows and columns of unit leadframes, to further increase throughput and reduce per unit cost. Solder balls 507 are shown disposed on the interior ends of leads 509, 519. The solder balls can 507 be placed in a solder ball drop mounting operation. Alternatively, solder can be disposed using screen printing or a drop on demand dispense method for a solder paste can be used. Lead-free or lead based solders can be used, increasingly lead-free eutectic solder balls can be used. In an example useful in the arrangements, tin, silver, and copper, (SnAgCu or “SAC”) solder balls can be used. Solder balls can be selected for different melting points to improve reliability for assembly, depending on whether more than one solder reflow process will be used. For example, in an application where additional devices will be mounted after the integrated system device is mounted, the first solder balls used may be chosen with an elevated temperature melting point. After the first solder joints are formed, additional solder balls can be used with a lower temperature melting point (lower when compared to the previous elevated temperature melting point) to allow additional solder reflow steps to proceed without damage to the first solder joints formed.

FIG. 5C illustrates the leadframe 530 of FIG. 5B after a device mounting step. In FIG. 5C, an integrated system device 420 is shown solder mounted to the leads 509, 519 of the leadframe 530. Because the solder joints are formed on the board side of the integrated system device 420, this mounting process can be referred to as a “flip chip” mounting process. In FIG. 5C, solder joints 508 are formed by placing conductive lands of the integrated system device 420 in contact with the solder balls 507, and a thermal solder reflow process is used to form solder joints 508 between the conductive lands and the leads 509, 519. The solder joints 508 provide both an electrical connection and a physical attachment between the integrated system device 420 and the leads 509, 519.

FIG. 5D illustrates, in a cross-sectional view, the elements of FIG. 5C, after additional processing. In FIG. 5D, mold compound 523 forms a package body for a microelectronic device package 500. The mold compound 523 covers the integrated system device 420, the solder joints 508, and portions of the leadframe 530 including portions of leads 509, and 519. The external portions of leads 509, 519 that are exposed from the mold compound 523 form terminals for the microelectronic device package 500. In the example arrangement, an SOIC or wide SOIC package can be used. The microelectronic device package 500 can be sized to have a clearance distance labeled “Dclr” (a distance between conductors of different voltage domains of at least 8 millimeters between the closest exposed portion of the lead 509 and the closest exposed portion of the lead 519, to ensure robust electrical isolation by preventing arcing or coupling through the air. The microelectronic device package 500 can be sized to have a minimum creepage distance labeled “Dcpg”, a possible current path over the mold compound 523 between an exposed portion of the lead 509, and an exposed portion of the lead 519, of at least 8 mm. Robust isolation between the first set of conductive leads and the second set of conductive leads that are in different voltage domains is achieved when the creepage and clearance distances are increased.

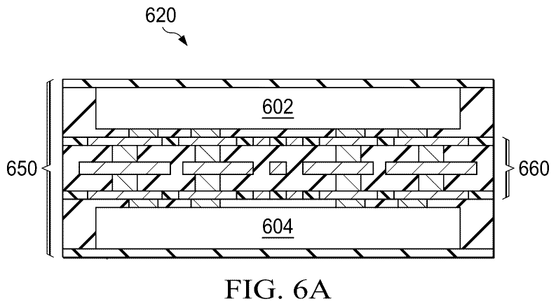

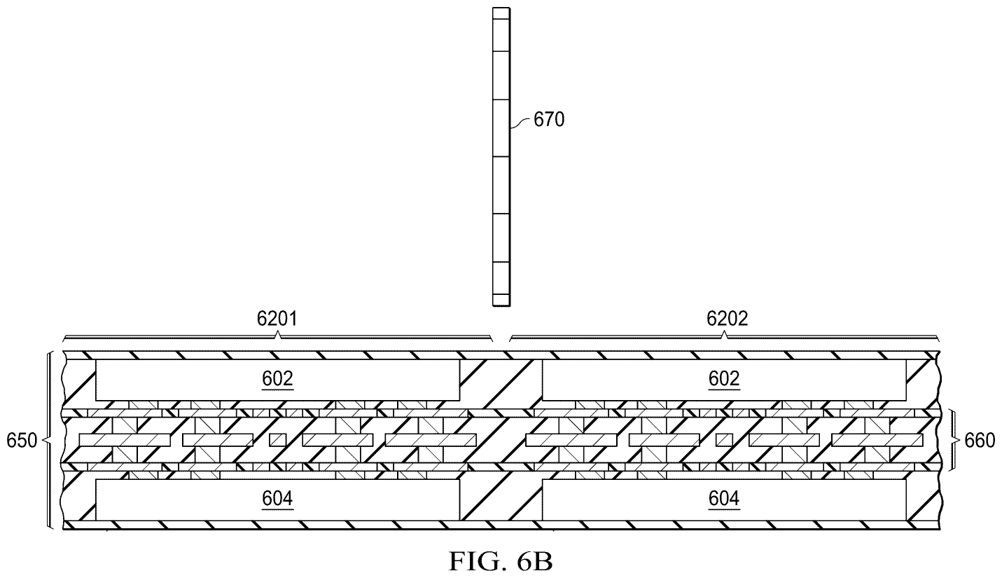

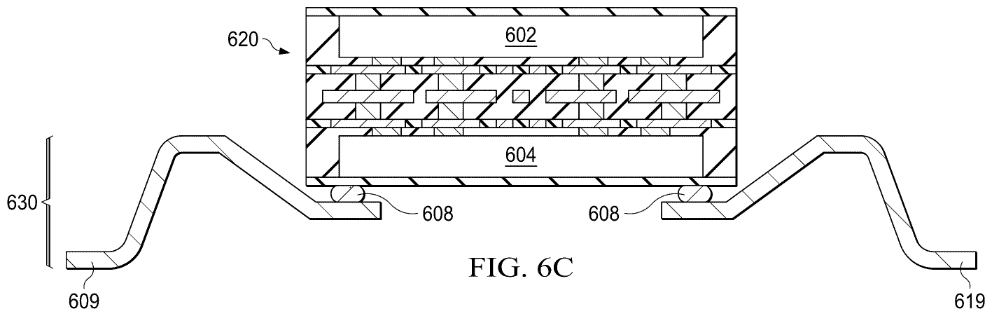

FIG. 6A illustrates, in a cross-sectional view, an alternative arrangement for an integrated system device 620. The integrated system device 620 has embedded semiconductor dies 602, 604 on opposing sides of trace level conductor layers in a multilayer dielectric material 650. Multilayer dielectric material 650 can be formed in the sequential additive build-up process described above, with repeated steps of conductor plating, dielectric deposition, and grinding to prepare for additional conductor plating. Conductors 660 include trace level conductor layers and connection level conductor layers between trace level conductor layers that can be formed using the sequential additive build-up processes described above. In contrast to the side-by-side positions of the semiconductor dies in the integrated system device 420 as shown in FIG. 5D, for example, in the integrated system device 620 the semiconductor dies can be embedded on opposite sides with the conductors 660 between the semiconductor dies 602, 604. In one example arrangement, similar to example arrangements described above, a transformer with isolation between a first voltage domain and a second voltage domain can be formed by forming a first coil spaced from a second coil using the conductors 660 and the dielectric material 650 to space the first and second coils. In an example, semiconductor dies that are controllers can be embedded with the coils in the integrated circuit device to form a DC-to-DC voltage converter circuit.

FIG. 6B illustrates, in another cross-sectional view, integrated system devices 6201, 6202 which are replicated integrated system devices corresponding to the integrated system device 620 of FIG. 6A, in a singulation operation. In FIG. 6B, a rotating saw 670 is shown cutting through the dielectric material 650 in a saw street between integrated system devices 6201, 6202, to separate the integrated system devices from one another. The integrated system devices can be formed as a panel of ten, hundreds or even thousands of devices processed simultaneously, to reduce unit costs. The integrated system devices can be delivered as a panel, or after singulation, as individual unit devices, for use by a pick and place tool for packaging.

FIG. 6C illustrates, in another cross-sectional view, an integrated system device 620 (which can be one of 6201 or 6202 in FIG. 6B) mounted to a leadframe 630. Although a single leadframe 630 is shown for purposes of explanation in FIG. 6C, in a practical assembly process the leadframe 630 would be part of a strip of adjacent unit leadframes in a row spaced from one another by saw streets of the leadframe material, or alternatively as one unit in an array or grid of unit leadframes in rows and columns spaced by saw streets. The solder joints 608 couple the leads 609, which can be arranged for a first voltage domain, and leads 619, which can be arranged for a second voltage domain isolated from the first voltage domain to the integrated system device 620. Solder joints 608 are formed from solder balls disposed on the interior ends of the leads, which are used in a thermal reflow process to attach the integrated system device 620 to the leads, and to electrically couple the integrated system device 620 to the leads 609, 619 of leadframe 630. The leadframe 630 is a downset leadframe with gull wing leads, the use of the downset leadframe increases the vertical distance above the leads 609, 619 in a packaged device, increasing the space available for the integrated system device 620 (when compared to a leadframe without the downset).

FIG. 6D illustrates, in a further cross-sectional view, the elements of FIG. 6C after an additional process step to form a microelectronic device package 600 for an alternative arrangement. In FIG. 6D, the elements are shown with mold compound 623 formed over integrated system device 620, the solder joints 608, and portions of the leads 609 and 619 of the leadframe 630. In an example process, a transfer mold tool is used to form mold compound 623. In the example process, thermoset mold compound, such as an epoxy resin mold compound, is provided as a solid at room temperature, either as a solid puck or as powdered mold compound. The mold compound is heated to a liquid state and then forced under hydraulic pressure through runners to fill a mold chase containing the leadframe 630 with the integrated system device 620 mounted to it. In a practical mold tool, many unit leadframes can be molded at the same time, which is an entire leadframe strip or array will be placed in the mold tool, and the microelectronic device packages for each of the unit leadframes will be molded at the same time to increase throughput and reduce per unit costs.

After the mold compound 623 cures to form a solid package body, the individual microelectronic device packages, such as 600, are separated from one another and the leadframe strip by cutting through the leadframe material in saw streets between the molded devices. Post mold processing including singulation, and lead trim and form can be performed to shape and align the leads 609, 619.

The arrangements advantageously provide a microelectronic device package with robust electrical isolation between sets of leads arranged for coupling to a first voltage domain and additional leads arranged for coupling to a second voltage domain. Semiconductor dies that are coupled to leads for each voltage domain, and passive components such as planar coils, are embedded in a dielectric material that isolates the elements of the two voltage domains in an integrated system device. In the arrangements, advantageously the integrated system device can be mounted to a leadframe using a single solder reflow process to mount the integrated system device to the leadframe. The coefficient of thermal expansion (CTE) for the mold compound (see mold compound 623 in FIG. 6D) that forms the package body and the CTE for the dielectric of the integrated system device (see 620 in FIG. 6D) are closely matched. The use of the arrangements therefore advantageously reduces thermal mismatch between the elements, so that delamination and cracking defects observed in prior approach microelectronic device packages (with semiconductor dies having a first CTE for a semiconductor material that are flip chip mounted separately to a package substrate having a substantially different CTE, and the package substrate then solder mounted to the leadframe), are reduced or eliminated by use of the arrangements. Assembly of the leaded packages is also simplified by use of the arrangements, which needs only a single solder reflow step to mount the integrated system device to the leadframe, instead of several solder reflow steps used in the prior approach to mount a first semiconductor die, a second semiconductor die and the package substrate to the leadframe, in separate thermal solder reflow steps.

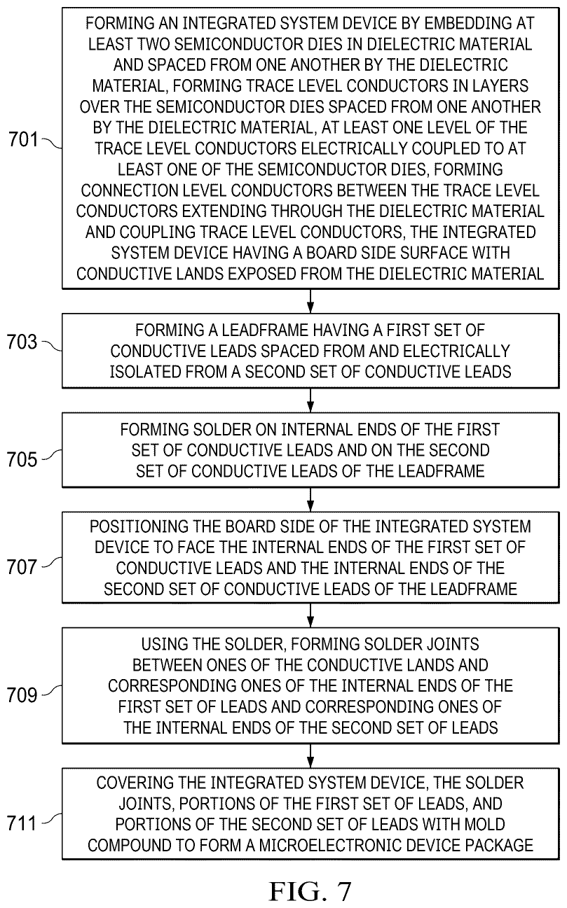

FIG. 7 illustrates, in a flow diagram, the steps used to form an integrated system device with multilayers of conductors and dielectric material for use in the arrangements.

At step 701, an integrated system device is formed by: embedding at least two semiconductor dies in dielectric material and spaced from one another by the dielectric material, forming trace level conductors in layers over the semiconductor dies and spaced from one another by the dielectric material, at least one layer of the trace level conductors electrically coupled to at least one of the semiconductor dies, forming connection level conductors between the trace level conductors extending through the dielectric material and coupling trace level conductors, the integrated system device having a board side surface with conductive lands exposed from the dielectric material. (See, for example, FIGS. 4A-4K, with integrated system device 420 (shown complete in FIG. 4K) having conductive lands 456 exposed from dielectric material 460). Conductive lands 456 are formed from a trace level conductor layer exposed from the dielectric material 460. The integrated system device 420 can be formed in a panel or array, and can be formed asynchronously from the remaining steps, at a different location, and by different fabricators, such as a substrate vendor or board vendor.

At step 703, the method continues by forming a leadframe having a first set of conductive leads spaced from and electrically isolated from a second set of conductive leads. (See, for example, FIG. 5B, leadframe 530 is shown in cross section with a first set of conductive leads 509, and a second set of conductive leads 519). Note that the leadframe can be formed at any time, independently from forming the integrated system device at step 701 and can be formed by a different fabricator than the integrated system device and at a different location.

The method continues at step 705, by forming solder on internal ends of the first set of conductive leads and on the second set of conductive leads of the leadframe. (See, for example, FIG. 5B with solder balls 507 deposited on the internal ends of the first set of conductive leads 509 and on the internal ends of the second set of conductive leads 519).

At step 707, the integrated system device is positioned for mounting to the leadframe by positioning the board side surface of the integrated system device to face the internal ends of the first set of conductive leads and the internal ends of the second set of conductive leads of the leadframe. At step 709, the method continues by using the solder, forming solder joints between ones of the conductive lands and corresponding ones of the internal ends of the first set of leads and corresponding ones of the internal ends of the second set of leads. (See, for example, leadframe 530 and integrated system device 420 as shown in FIG. 5C).

At step 711, the method completes by covering the integrated system device, the solder joints, portions of the first set of leads, and portions of the second set of leads with mold compound to form a microelectronic device package. (See, for example, microelectronic device package 500 in FIG. 5D, or microelectronic device package 600 in FIG. 6D with mold compound 623).

The use of the integrated system device and methods for mounting it of the arrangements provides microelectronic device packages including semiconductor dies with integral passive components that are isolated from one another to provide high isolation voltages. Existing materials and assembly tools are used to form the arrangements, and the arrangements are low in cost. The use of the arrangements allows microelectronic device packages with simplified packaging processes and increased reliability, when compared to microelectronic deice packages formed with similar components but formed without use of the arrangements.

Modifications are possible in the described arrangements, and other alternative arrangements are possible within the scope of the claims.

What is claimed is:

1. A method, comprising:
forming an integrated system device by performing:
embedding at least two semiconductor dies spaced from one another in dielectric material, forming layers of trace level conductors layers over the dielectric material, the layers of trace level conductors spaced by additional dielectric material, at least one of the trace level conductors electrically coupled to at least one of the at least two semiconductor dies, forming layers of connection level conductors extending through the additional dielectric material and coupling trace level conductors, the integrated system device having a board side surface with conductive lands exposed from the dielectric material;
depositing solder balls on internal ends of a first set of conductive leads that are positioned on one side of a package substrate and on internal ends of a second set of conductive leads that are positioned on an opposite side of a package substrate, the first set of conductive leads spaced from the second set of conductive leads;
positioning the board side surface of the integrated system device to face the internal ends of the first set of conductive leads and the internal ends of the second set of conductive leads;
using the solder balls, forming solder joints between ones of the conductive lands and corresponding ones of the internal ends of the first set of leads and corresponding ones of the internal ends of the second set of leads; and
covering the integrated system device, the solder joints, portions of the first set and second set of leads with mold compound to form a microelectronic device package.

2. The method of claim 1, wherein embedding at least two semiconductor dies spaced from one another in dielectric material further comprises:
forming a first layer of the dielectric material;
mounting the at least two semiconductor dies on the first layer of dielectric material with bond pads facing away from the layer of the dielectric material;
covering the at least two semiconductor dies with an additional layer of dielectric material;
exposing the bond pads from the additional layer of dielectric material;
patterning a first layer of trace level conductors over the additional layer of dielectric material;
depositing another additional layer of dielectric material over the first layer of trace level conductors;
grinding the another additional layer of dielectric material to expose a surface of the first layer of trace level conductors;
patterning a first layer of connection level conductors over the surface and contacting the first layer of trace level conductors; and
forming further additional layers of dielectric material, further additional layers of trace level conductors spaced by the further additional layers of dielectric material, and further additional layers of connection level conductors coupling the layers of trace level conductors to form the integrated system device.

3. The method of claim 2 and further comprising:
prior to patterning the first level of trace level conductors, exposing the bond pads from the additional layer of dielectric material using a laser to form via openings; and
depositing conductor material in the via openings to form filled vias contacting the bond pads.

4. The method of claim 1, and further comprising:
prior to mounting the at least two semiconductor dies, forming conductive post connects extending from bond pads on the at least two semiconductor dies.

5. The method of claim 1, wherein the microelectronic device package is an isolation package having the first set of conductive leads extending away from the mold compound to form a first set of terminals, and having the second set of conductive leads extending away from the mold compound to form a second set of terminals spaced from and electrically isolated from the first set of terminals.

6. The method of claim 1, wherein the at least two semiconductor dies further comprise a first semiconductor die coupled to the first set of conductive leads and a second semiconductor die coupled to the second set of conductive leads, the first semiconductor die electrically isolated from the second semiconductor die.

7. The method of claim 6, wherein the integrated system device further comprises a first coil formed in the trace level conductors, and a second coil formed in the trace level conductors, the first coil spaced from the second coil by the layers of the additional dielectric material.

8. The method of claim 7, wherein a transformer is formed using the first coil and the second coil.

9. The method of claim 8, wherein the first semiconductor die is electrically coupled to the first coil.

10. The method of claim 8, wherein the second semiconductor die is electrically coupled to the second coil.

11. A microelectronic device package, comprising:
an integrated system device, further comprising:
at least two semiconductor dies embedded in dielectric material and spaced from one another by the dielectric material;
layers of trace level conductors formed over the at least two semiconductor dies and spaced from one another by layers of additional dielectric material; and
at least one of the layers of trace level conductors electrically coupled to at least one of the at least two semiconductor dies, layers of connection level conductors extending through the layers of additional dielectric material between the layers of trace level conductors and coupling trace level conductors, the integrated system device having a board side surface with conductive lands formed by one of the layers of trace level conductors or of one of the layers of connection level conductors exposed from the layers of additional dielectric material;
a first set of conductive leads on one side of a package substrate spaced from and electrically isolated from a second set of conductive leads on an opposite side of the package substrate;
the conductive lands of the board side surface of the integrated system device mounted to internal ends of the first set of conductive leads and to internal ends of the second set of conductive leads; and
mold compound covering the integrated system device, portions of the first set of leads, and portions of the second set of leads.

12. The microelectronic device package of claim 11, wherein the integrated system device further comprises:
a first coil formed in the layers of trace level conductors of the integrated system device; and
a second coil formed in the layers of trace level conductors of the integrated system device and the second coil spaced from the first coil by the layers of additional dielectric material.

13. The microelectronic device package of claim 12, wherein the at least two semiconductor dies comprise a first semiconductor die and a second semiconductor die, and further comprising:
the first semiconductor die coupled to the first coil and electrically isolated from the second coil and from the second semiconductor die.

14. The microelectronic device package of claim 13, and further comprising the second semiconductor die coupled to the second coil, and electrically isolated from the first coil, and wherein a transformer is formed from the first coil and the second coil.

15. The microelectronic device package of claim 13, wherein the first set of conductive leads extends from the mold compound and forms a first set of terminals.

16. The microelectronic device package of claim 15, wherein the second set of conductive leads extends from the mold compound and forms a second set of terminals, the second set of terminals spaced from and electrically isolated from the first set of terminals.

17. The microelectronic device package of claim 14, wherein the microelectronic device package is a DC-DC converter.

18. The microelectronic device package of claim 11, wherein the at least two semiconductor dies comprise a first semiconductor die and a second semiconductor die placed spaced apart and positioned side by side.

19. The microelectronic device package of claim 11, wherein the at least two semiconductor dies comprise a first semiconductor die and a second semiconductor die that are placed spaced apart and facing one another with the layers of trace level conductors between the at least two semiconductor dies.

20. A method, comprising:
forming an integrated system device, by performing:
embedding a first semiconductor die and a second semiconductor die in dielectric material and spaced from one another by the dielectric material, forming layers of trace level conductors over the first semiconductor die and the second semiconductor die, the layers of trace level conductors spaced from one another by additional layers of dielectric material, at least one level of the trace level conductors electrically coupled to the first semiconductor die or the second semiconductor die, forming layers of connection level conductors between the layers of trace level conductors extending through the additional layers of dielectric material and coupling layers of the trace level conductors, forming a first coil and a second coil using layers of the trace level conductors, the first coil and the second coil spaced from one another by the layers of additional dielectric material and electrically isolated from one another, the first semiconductor die coupled to the first coil and electrically isolated from the second coil, the second semiconductor die coupled to the second coil and electrically isolated from the first coil, and forming conductive lands from one of the layers of trace level conductors or from one of the layers of connection level conductors exposed from the additional layers of dielectric material on a board side surface of the integrated system device;
forming solder balls on internal ends of a first set of conductive leads on one side of a package substrate and on internal ends of a second set of conductive leads on an opposite side of the package substrate;
positioning the board side surface of the integrated system device to face the internal ends of the first set of conductive leads and the internal ends of the second set of conductive leads;
using the solder balls, forming solder joints between ones of the conductive lands and corresponding ones of the internal ends of the first set of conductive leads and corresponding ones of the internal ends of the second set of conductive leads; and
covering the integrated system device, the solder joints, portions of the first set of conductive leads, and portions of the second set of conductive leads with mold compound to form a microelectronic device package.
